(19) United States
(12) Patent Application Publication
(10) Pub. No.: US 2008/0210454 A1
(43) Pub. Date: Sep. 4, 2008

(54) Composite Superconductor Cable Produced by Transposing Planar Subconductors

(76) Inventors: Michael Fee, Lower Hutt (NZ); Nicholas Long, Lower Hutt (NL); Michael Staines, Lower Hutt (NL)

Correspondence Address: DANN, DORFMAN, HERRELL & SKILLMAN, 1601 MARKET STREET, SUITE 2400, PHILADELPHIA, PA, 19103-2307, US

(21) Appl. No.: 10/594,463

(22) PCT Filed: Mar. 31, 2005
(86) PCT No.: PCT/NZ2005/000064

§ 371 Date: Apr. 18, 2008

(30) Foreign Application Priority Data
Mar. 31, 2004 (NZ) 532066

(51) Int. Cl. H01B 12/06; H01L 39/24

(52) U.S. Cl. 174/125.1; 29/599

(57) ABSTRACT

A method of forming a low AC loss, fully transposed cabled superconductor from multiple superconducting subconductors cut in a serpentine form from a wider superconducting tape is disclosed. By assembling pre-cut subconductor tapes a cable with a short transposition pitch length can be formed without excessive in-plane or out-of-plane deformation of the tape which could otherwise cause degradation of its superconducting performance. The transposition may be in either Roebel bar or Rutherford cable geometry.

### BACKGROUND

1. Field of Invention

Many applications of high T_{c} superconductors (HTS), such as power transformers and high current magnets, require higher current than the capacity of presently available conductor tape. High currents can be attained by forming cables of multiple subconductors in which the individual conductors or conductor elements are continuously transposed such that each subconductor is electromagnetically equivalent. In this way current is equally shared and AC losses minimised. A spiral arrangement of conductors on the surface of a cylinder achieves this, but with inefficient use of space so that the overall engineering current density of the winding is reduced. The Roebel bar and Rutherford cable are transposed conductor cable configurations which combine high packing density with rectangular cross-section. The Rutherford cable has been used extensively with low T_{c} superconductors—see for example, M. N. Wilson, “Superconductors and accelerators: the Good Companions”, IEEE Transactions on Applied Superconductivity, Vol. 9, No. 2, June 1999, pages 111-121. The Roebel bar is long established as a high current copper conductor configuration for transformers and has been fabricated using HTS conductor—see J. Nishioka, Y. Hikichi, T. Hasegawa, S. Nagaya, N. Kashima, K Goto, C Suzuki, T Saitoh, “Development of Bi-2223 multifilament tapes for transposed segment conductors”, Physica C volumes, 378-381 (2002) 1070-1072; V Hussennether, M. Oomen, M. Leghissa, H.-W. Neumüller, “DC and AC properties of Bi-2223 cabled conductors designed for high-current applications”, Physica C 401 (2004) 135-139; and Suzuki et. al. “Strain properties of transposed segment conductors for a transmission cable”, Physica C, volumes 392-396, (2003) pages 1186-1191.

In addition to the requirement for high-current conductor most AC applications of HTS demand low AC loss. In general this means that conductors should be transposed, electrically decoupled, and have minimal transverse dimensions. Because of the typically ribbon-like form of HTS conductors, it may be desirable for AC applications to manufacture conductor with narrower strand width than the usual DC conductor. An application might be, for example, in parts of windings exposed to appreciable AC fields oriented perpendicular to the face of the conductor. This narrow strand conductor will need to be made into a transposed multistrand conductor to give adequate current capacity for many applications. The shorter the transposition twist pitch, the lower the effective interstrand resistivity can be while still keeping the strands magnetically decoupled—see M. N. Wilson, “Superconductors and accelerators: the Good Companions”, IEEE Transactions on Applied Superconductivity, Vol. 9, No. 2, June 1999, pages 111-121, equation 3. Provided decoupling is achieved, lower interstrand resistivity improves electrical and thermal stability and facilitates electrical connection to the cable.

There are presently two main HTS tape conductor types in production or development. Multifilament silver or silver alloy-sheathed composite conductor using the superconducting cuprate of composition (Bi, Pb)_{2.1}Sr₂Ca₂Cu₃Oₓ (otherwise known as Bi-2223) is produced in commercial quantities by a powder-in-tube (PIT) manufacturing process involving drawing, rolling, and thermal treatment processes. A typical conductor will consist of approximately 55 HTS filaments embedded in a silver or silver alloy matrix, will have a cross-section of about 4 mm by 0.2 mm and a critical current at 77 K in self-field of up to 150 A.

Roebel-type cabled conductor made from PIT subconductors has been disclosed in the literature—see J. Nishioka, Y. Hikichi, T. Hasegawa, S. Nagaya, N. Kashima, K Goto, C Suzuki, T Saitoh, “Development of Bi-2223 multifilament tapes for transposed segment conductors”, Physica C 378-381 (2002) 1070-1072; and V Hussennether, M. Oomen, M. Leghissa, H. -W. Neumüller, “DC and AC properties of Bi-2223 cabled conductors designed for high-current applications”, Physica C 401 (2004) 135-139.

A method for forming Roebel bar cable by controlled bending of tapes of this type is described in U.S. Pat. No. 6,725,071 to C Albrecht, P Kummeth, P Massek, titled “Fully transposed high Tc composite superconductor, method for producing the same and its use”. This takes account of the sensitivity of PIT tape to deformation-induced damage by imposing minimum limits on the edge-wise (i.e. in the plane of the tape) bending radius and bending zone length respectively of 100 times and 20 times the tape width. The resulting cable pitch for complete transposition is comparatively long.

“Second generation” or 20 HTS conductor is produced as a thin film of YBa₂Cu₃O₇ (Y-123) approximately 1 μm thick on a substrate of a base metal tape coated with various oxide films—see for example A. P. Malozemoff, D. T. Verebelyi, S. Fleshler, D. Aized and D. Yu “HTS Wire: status and prospects”, Physica C, volume 386, (2003) pages, 424-430. Transposed 2G conductor has been disclosed—see Suzuki, Goto, Saitoh and Nakatsuka, “Strain Properties of Transposed Segment Conductors for a Transmission Cable”, Physica C 392-396 (2003) 1186-1191. See also Japanese patent application publications 2003092033 and 2004030907.

Methods have been developed for laminating 20 wire with copper tape to protect the tape from thermal-electrical instability and, by locating the HTS film at or near the neutral axis for flat-wise (out-of-plane) bending, from mechanical stress. It is envisaged that standard conductor with around 4 mm width will be slit from the wide conductor. Edge-wise bending of 2G wire to form cables will, like PIT tape, be subject to limits on the minimum bending radius. There is, at present, no published data on the sensitivity of 20 wire to edgewise bending. However, due to its different mechanical properties compared with silver and silver-alloy sheath material one might expect even more difficulty in edgewise deformation.

### SUMMARY OF INVENTION

In broad terms in one aspect the invention comprises a method for forming a high temperature superconductor (HTS) conductor or cable comprising transposed conductor elements comprising:

forming a layer of an HTS on one or more substrates and cutting the substrate(s) with an HTS layer thereon or at least one substrate into a multiple number of generally longitudinally extending serpentine conductor elements each comprising a series of element portions which periodically change direction relative to one another in a plane of the substrate, or cutting one or more planar substrates to form a multiple number of generally longitudinally extending serpentine substrate elements each comprising a series of element portions which periodically change direction relative to one another in a plane of the substrate, so that said serpentine conductor elements are cut from the larger substrate back-to-back with similarly oriented element portions of the serpentine conductor elements being cut from common parts of the larger substrate across a width of the substrate, and forming a layer of an HTS on a surface of the serpentine substrate elements, and

interleaving such serpentine conductor elements to form a longitudinally extending transposed conductor HTS conductor or cable.

In one form the method includes cutting the substrate(s) to form a multiple number of generally longitudinally extending serpentine conductor elements each comprising a first series of element portions having a generally common longitudinal axis and a second series of element portion having a generally common longitudinal axis which is spaced from the longitudinal axis of said first series of element portions in a plane of the substrate, with connecting portions of the conductor elements between. Typically the element portions of said first series of conductor elements and the element portions of said second series of conductor elements are longer than connecting portions between.

In another form the method includes cutting the substrate(s) with the HTS layer thereon to form a multiple number of generally longitudinally extending serpentine conductor elements each comprising a first series of spaced generally parallel element portions which extend at an angle across a longitudinal axis of the conductor element in a first direction and a second series of spaced generally parallel element portions which extend across the longitudinal axis of the conductor element in an opposite direction.

Preferably the method includes cutting three or more, and more preferably five or more, of said longitudinally extending conductor or substrate elements side by side from a common substrate.

The resulting serpentine conductor elements are interleaved to form a longitudinally extending HTS conductor or cable in which individual conductor elements are transposed relative to other conductor elements typically both in the plane of the conductor elements and orthogonal to the plane of the conductor elements. Preferably also each serpentine conductor element is transposed with an adjacent conductor element in plane, out of plane, or both, once per each said element portion of each conductor element. Preferably at least four conductor elements are interleaved to form a longitudinally extending transposed conductor HTS conductor or cable.

Preferably at least some and typically all of the conductor elements are interleaved with an orientation such that the HTS layers of adjacent conductor elements face and directly or indirectly electrically contact each other at points along the length of the conductor or cable.

The substrate may comprise a metal or metal alloy and will typically be a metal or metal alloy tape. Preferably at least the surface of the substrate is a crystallographically aligned oxide layer. One or more buffer layers may be provided between the substrate and the HTS. An overlayer may be provided over the HTS layer, of a noble metal or copper or a metal alloy.

Preferably the layer of an HTS is a film of the HTS with Jc>10⁴ A/cm² (DC, 77K, self field). The HTS may be an R—Ba—Cu—O HTS where R is Y or a rare earth element. The HTS may comprise substantially R Ba₂ Cu₃ O₇ where R is Y, Nd, Sm, Eu, Gd, Tb, Dy, Ho, Er, Tm, or Yb or a combination thereof

In another aspect the invention comprises a high temperature superconductor (HTS) conductor or cable comprising a number of transposed conductor elements which comprise a layer of an HTS on a substrate element cut in a longitudinally extending serpentine form from a larger substrate back-to-back with similarly oriented element portions being cut from common parts of the larger substrate across the width of the larger substrate.

The term ‘comprising’ as used in this specification and claims means ‘consisting at least in part of’, that is to say when interrupting independent claims including that term, the features prefaced by that term in each claim will need to be present but other features can also be present.

### BRIEF DESCRIPTION OF THE FIGURES

The invention is further described with reference to the accompanying figures in which:

FIGS. 1a and 1b schematically show shapes of single conductor elements subconductors to create a Rutherford-type conductor or cable.

FIG. 2a is a schematic top view of a Rutherford cable formed from four serpentine conductor elements or subconductors as shown in FIG. 1. FIG. 2b shows the same Rutherford cable with a former (shaded) positioned between top and bottom layers.

FIG. 3 also schematically shows an assembled Rutherford cable formed from four subconductors as shown in FIG. 1.

FIG. 4 shows a shape of a single conductor element or subconductor to create a Roebel type cable, of cable width 2×B₁, with conductor width B₁ in the straight sections and B₂ in the crossover sections, and where the transposition length of the cable is L.

FIG. 5 schematically shows an assembled Roebel cable formed from ten subconductors as shown in FIG. 4.

FIG. 6 schematically shows a pattern of cuts on a wide 2G HTS tape to make subconductors for Roebel type cable. Shaded areas show waste material.

FIG. 7 schematically shows a pattern of cuts on a wide 2G HTS tape to make subconductors for Rutherford type cable. Shaded areas show waste material.

FIG. 8 schematically shows in cross-section a five subconductor cable illustrating in FIG. 8a non-current sharing and in FIG. 8b current sharing configurations. The layer 21 is a stabilisation layer and the layer 22 is the substrate layer. The HTS layer, labelled 23 is between the substrate and the stabilisation layer.

FIG. 9 schematically shows a different cable architecture which can be used to create high current density configurations. FIGS. 9a and 9c show different cross-section arrangements of a single subconductor, with a single sided HTS coating and double sided HTS coating respectively. FIG. 9b is a high current density configuration with a single sided coating of HTS. FIG. 9d is a high current density configuration with a double sided coating of HTS.

### DETAILED DESCRIPTION OF PREFERRED FORMS

The present invention comprises to the forming of high current and/or low AC loss transposed conductor or cable from 2G wire or similar coated conductor without the need for substantial in-plane deformation by, in one form, cutting the serpentine subconductors from one or more wider common planar substrate or tape. The required number of subconductors may then be assembled or interleaved, typically using a planetary winder with appropriate lengthwise displacement of each subconductor in cyclic order, to form a transposed conductor or cable. This may then be further treated to fix the individual subconductors in place for subsequent handling, manufacturing, and implementation operations, preferably using methods which optimise the interstrand resistivity to achieve low AC loss.

The subconductors may be cut or precut from the substrate(s), such that wastage may be minimized, before or after formation of the superconducting layer and all or some of any buffer layers on the substrate, to facilitate separation of the subconductors with minimal damage to the superconducting properties.

The HTS layer may, for example, consist of a thin layer of YBa₂Cu₃O₇ or other cuprate superconductor which is epitaxially grown on the substrate, or other forms of non-epitaxial HTS which may be deposited on buffered base metal substrate tapes. The HTS may be grown on one side or both sides of the substrate.

The substrate consists of a metal tape which may be coated with single or multiple buffer layers. To create the crystal alignment in the YBCO the metal tape may, for example, be nickel or nickel alloy which is processed both mechanically and thermally to form a tape in which all the crystals are highly aligned. This process is known as rolling assisted biaxial texturing or RABiTS—see A. Goyal et al., “Strengthened, biaxially textured Ni substrate with small alloying additions for coated conductor applications”, Physica C, 382 (2002), 251-262 2002. The buffers then transfer the crystal alignment of the substrate through to the superconductor layer. Alternatively the texture may be originated in the buffer layers through “Ion beam assisted deposition” or “Inclined substrate deposition”. In ion-beam assisted deposition a sputter deposited film of yttria stabilised zirconia or magnesium oxide is textured by continually bombarding the growing film with Ar⁺ ions—see Y. Iijima et al., “Reel to reel continuous formation of Y-123 Coated conductors by IBAD and PLD method”, IEEE Trans. Appl. Supercon 11, (2001) 2816. In inclined substrate deposition the anisotropy in growth rates for different axes of MgO is exploited to create the crystal alignment—see K. Fujino et al., “Development of RE123 coated conductor by ISD method”, Physica C, 392-396, (2003) 815-820.

On top of the superconductor layer may be deposited a noble metal cap layer and/or copper stabilisation layer. Two such tapes may be joined “face to face” to form a composite with two superconducting layers in a single element.

The 2G HTS tape substrate may be, for example, manufactured in 10 cm width, laminated on the HTS face or faces with a copper or alloy stabiliser tape, and cut into multiple subconductors of the desired serpentine shape using for example mechanical slitting, fine blanking, laser or fluid jet cutting, or other cutting means. Each subconductor may typically be of thickness 50 microns to 500 microns with a typical thickness of 100-200 microns, and of average width 200 microns to 10 mm, with a typical width of 1 mm to 2 mm, for example. The subconductors typically have a rectangular or near rectangular cross sectional shape.

Coating with copper or other metal or alloy layer or layers using electroplating or other means may be carried out before or after cutting depending on the need for hermetic protection of the edge of the HTS layer. The mechanical properties and thickness of the stabiliser and any plated layers are preferably selected to locate the HTS film at the mechanical neutral axis so that out-of-plane bending of the composite conductor with a small radius of curvature could be tolerated without damage.

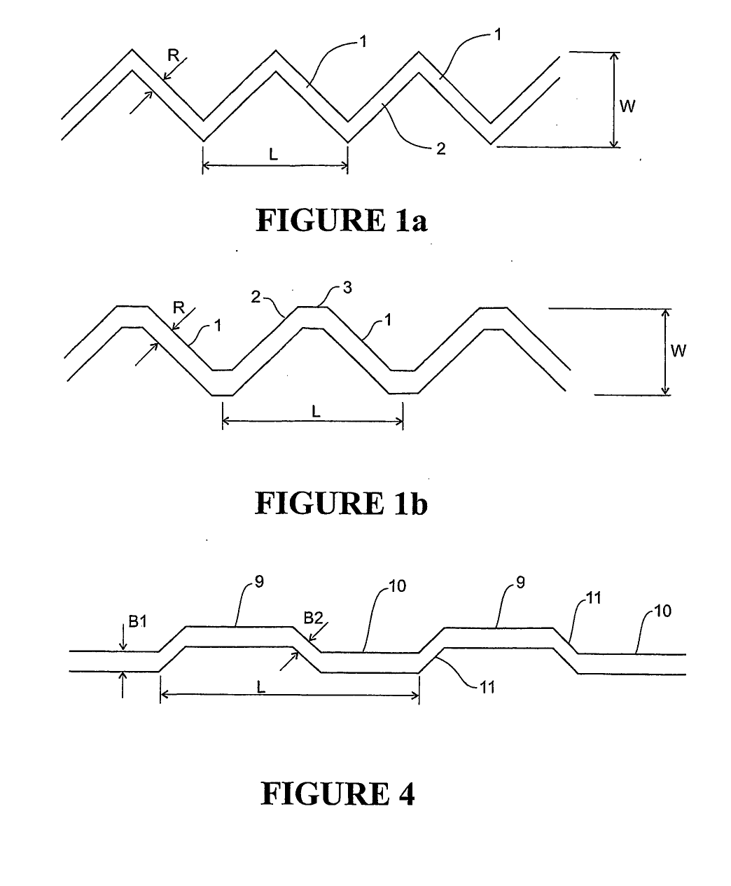

In the case of a conductor or cable of width W formed of subconductors with a Rutherford transposition the individual conductor elements or subconductors have the general form shown in FIG. 1a with conductor width W and where L is the transposition distance for the cable. A first series of generally parallel element portions 1 extend at an angle across a longitudinal axis of the subconductor in a first direction and a second series of spaced generally parallel element portions 2 extend across the longitudinal axis of the subconductor in an opposite direction. Straight connecting portions 3 at the turning sections at the edges may be added as in FIG. 1b. The bend required for the vertical transposition by one subconductor width is accommodated in the turning sections.

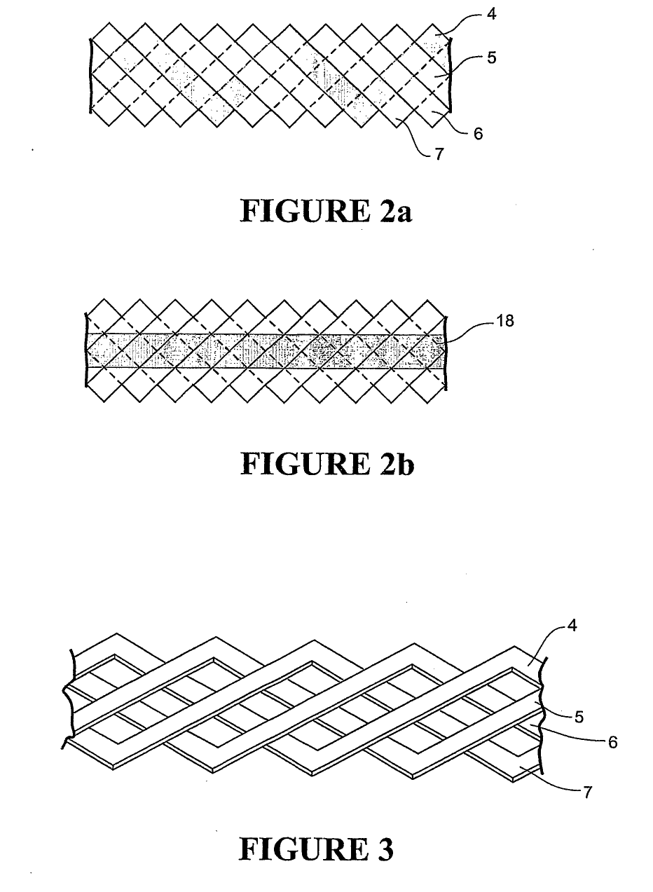

FIG. 2a schematically shows the layout of a 4-subconductor Rutherford cable, the four subconductors being indicated at 4-7. The dashed lines show obscured parts of the subconductors. The shaded region shows the continuity of a single strip subconductor 1 with the lighter shaded regions obscured. The cable may be wound with or without a resistive core schematically indicated at 8 (shaded) separating two layers of the cable as shown in FIG. 2b. The use of a resistive core is well known in the field—see for example, J D Adam et al, “Rutherford cables with anisotropic transverse resistance”, IEEE Transactions on Applied Superconductivity, Vol. 7, No. 2, June 1997, 958-961). The core for example may have a thickness of 25 microns to 1 mm and typically about 50 microns. The core is preferably of a non-magnetic metal alloy.

FIG. 3 also schematically shows an assembled Rutherford cable comprising four subconductors 4-7 of the form shown in FIG. 1.

In the case of a conductor or cable formed with a Roebel bar transposition the individual subconductors may be of a form shown in FIG. 4, consisting of alternating relatively long straight portions 9 and 10 with shorter cross-over or connecting portions 11 between. The cross-over sections 11 may have a sinuous shape (for example with the edges following a sinusoidal path) rather than the straight -sided cross-overs shown. However, for the same length of cross-over, more sinuous shapes will have a more constricted cross-section and are not favoured on account of the reduced local current carrying capacity. Each subconductor thus comprises a first series of element portions 9 having a generally common longitudinal axis and a second series of element portions 10 having a generally common longitudinal axis which is spaced from the longitudinal axis of said first series of element portions 9 in the plane of the substrate, with the connecting portions 11 between of cable width 2×B₁, with conductor width B₁ in the straight sections and B₂ in the crossover sections, and where the transposition length of the cable is L.

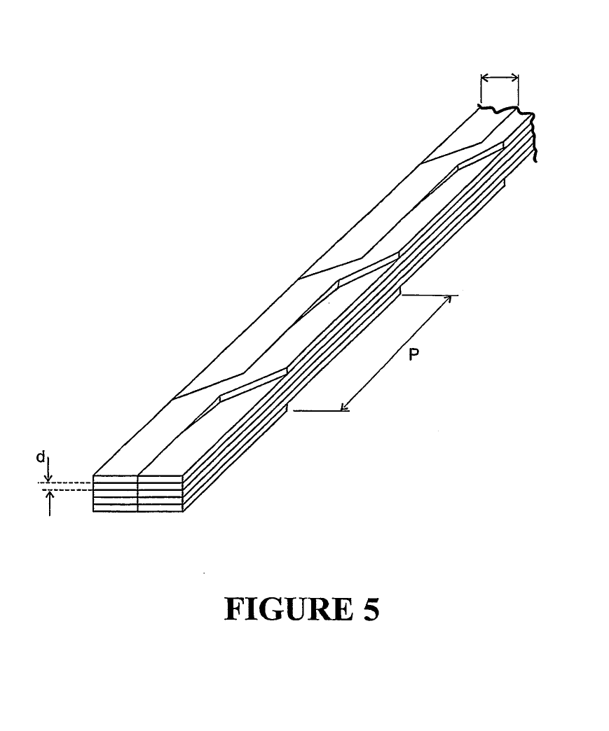

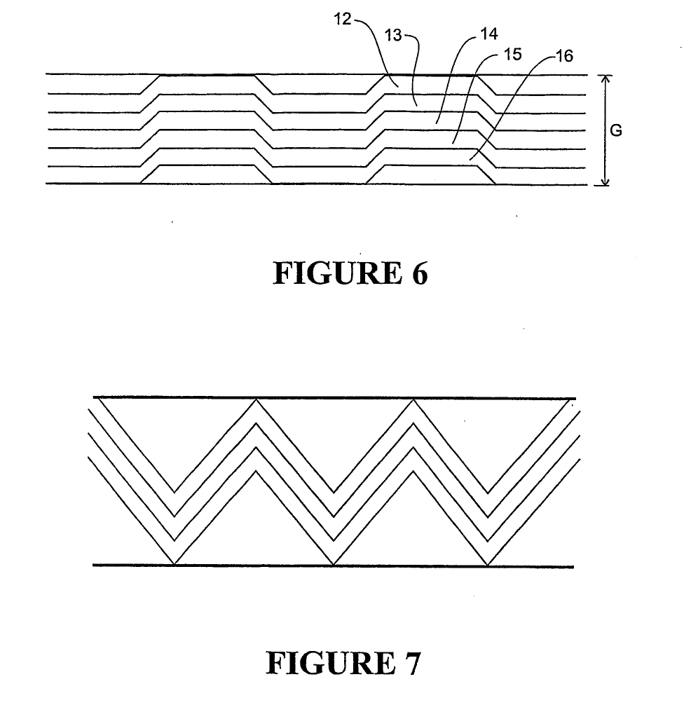

FIG. 5 schematically shows a Roebel-type cable formed from ten subconductors, the cable has subconductor width w, thickness d and transposition pitch p. Neglecting any material wasted along the margins of the cuts, the subconductors can be formed with the wastage of only one track width from the substrate, as schematically shown in FIG. 6, which shows how five subconductors 12-16 may be cut from a single substrate 10 of width G, and in which the wastage material is shown shaded and unreferenced. For example, only about 4% would be discarded in the case of 4 mm track width and 10 cm manufactured width. Appropriately spaced out-of-plane bends, as may be required for the vertical cycling of the subconductors in the Roebel bar stacks if the conductor faces are to be maintained parallel to the cable axis, may be included. Planetary winding equipment may again be used to transpose the conductor.

FIG. 7 is similar to FIG. 6 but shows how subconductors for Roebel type cable may be cut from a common substrate, with shaded areas again showing waste material.

In either case the shape for the subconductors is chosen so as to provide as uniform as possible a superconducting cross-section. Straight sections are preferred over sinuous profiles for this reason. The superconducting current will be limited by the region with minimum cross section. At the same time the utilisation of as much as possible of the original substrate is also desirable.

Each conductor or cable may contain for example 2-100 subconductors, with a typical composite conductor or cable containing 5-40 strands.

The transposition length is determined by the number of strands. In the case of a Roebel-type cable of N subconductors the transposition length L is given by

L=N(C+D)

where C is the length of the cross-over section of the subconductor profile and D is an allowance for out-of-plane bends or relative displacement of the subconductors required to assemble the cable without excessive twisting of individual strands. Preferably the cable is assembled such that D is maintained at the minimum length required to prevent mechanical damage to the strands by in plane or out of plane deformation.

The method described for forming Roebel and Rutherford type cables is compatible with fully insulated subconductors or with more or less conductive or resistive material bonding the subconductors together and providing electrical connectivity as required for optimal electromagnetic decoupling, electrical stabilisation, and for transfer of current at splices and contacts. For example, the subconductors may be electrically connected and bonded by solder or by the heat treatment of copper or other metallic coating to produce an oxide layer with optimal resistivity.

In a preferred form each subconductor will have an adherent, continuous, high resistivity coating preferably with a thickness range of 1 micron to 5 microns. The high resistivity coating may for example, be formed from sol-gel deposition or decomposition of a metal organic solution. As a further example, the high resistivity coating may be formed from oxidation of a precursor metal layer. The oxidation must be controlled so as not to oxidise the copper stabilisation layer in contact with the superconducting layer. The precursor metal layer may for example, be formed by electroplating, physical vapour deposition, or electroless plating.

The final cable may for example, be heat treated so that the high resistivity coating of each subconductor is diffusion bonded to a neighbouring subconductor.

The high resistivity oxide coating may be an oxide of a transition metal, including tin, bismuth, gallium, antimony, zinc, iron, nickel, niobium, tantalum, zirconium and/or indium or alloys therof with each other. The oxide coating has a preferred resistivity of greater than about 10 microohms/cm.

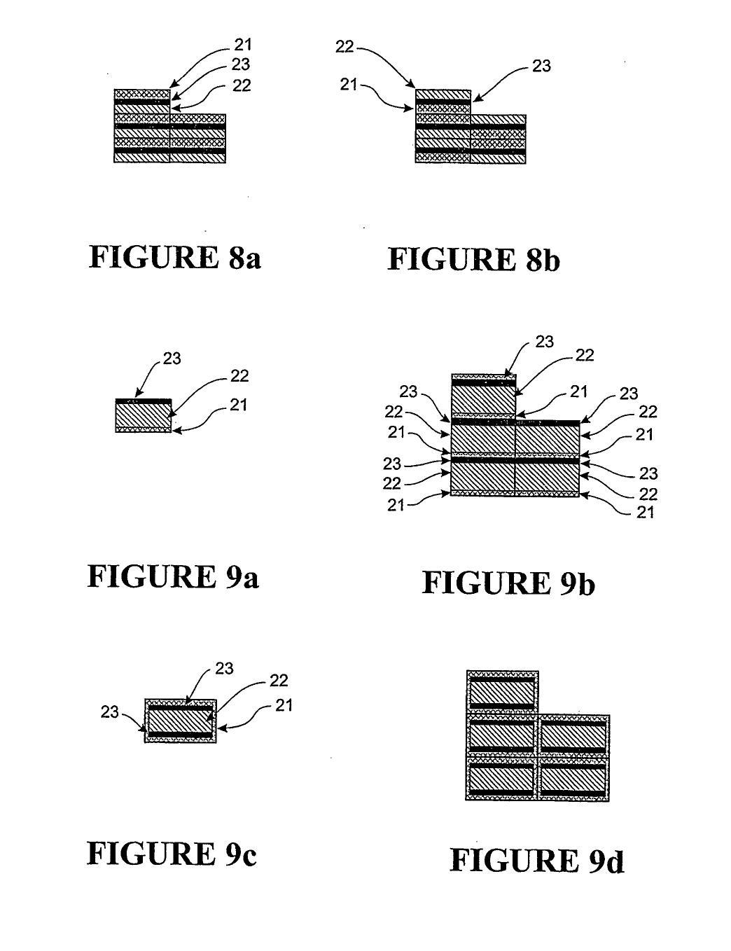

In a further preferred embodiment a conductor or cable architecture may be used to facilitate current sharing between the subconductors. This is not useful for applications requiring low AC loss but is useful for applications where a high total current is required. In this embodiment there is no high resistivity material added between subconductors and half the subconductors have reversed orientation so that the HTS layers are face to face and connected through high conductivity paths. This is illustrated for a five subconductor cable in FIG. 8 where 2 out of 5 subconductors are reversed. For a 2N+1 subconductor cable, either N Or equivalently N+1 subconductors can be reversed. The layer 21 is a stabilisation layer and the layer 22 is the substrate layer. The HTS layer, labelled 23 is between the substrate and the stabilisation layer.

In a further preferred embodiment the conductor may be arranged to carry very high current density. This can be achieved by using the substrate material for partial stabilization as shown in FIG. 9b. In this configuration the subconductors will preferably be bonded together by solder. In another configuration the subconductors may have superconducting layers on both faces of the strand and be laminated or electroplated with a stabilizing layer of copper. The subconductors are then soldered or otherwise joined together to facilitate current sharing between all the subconductors FIGS. 9a and 9c show different cross-section arrangements of a single subconductor, with a single sided HTS coating and double sided HTS coating respectively. FIG. 9b is a high current density configuration with a single sided coating of HTS. FIG. 9d is a high current density configuration with a double sided coating of HTS.

In the forgoing either a layer of the HTS is formed on the planar substrate(s) and then the substrate(s) are cut to form the subconductors, or alternatively the planar substrate(s) are cut to form the subconductors which are then coated with the HTS.

The final conductor may be insulated by wrapping with a paper insulation or covering with a polymer insulation by means known to those skilled in the art. The insulation may include high dielectric filler materials to increase the thermal conductivity of the insulation and hence the effectiveness of heat transfer from the cable.

The forgoing describes the invention including preferred forms thereof. Alterations and modifications as would be obvious to those skilled in the art are intended to be incorporated within the scope thereof as defined in the accompanying claims.

1. A method for forming a high temperature superconductor (HTS) conductor or cable comprising transposed conductor elements comprising:
forming a layer of an HTS on one or more substrates and cutting the substrate(s) with an HTS layer thereon or at least one substrate into a multiple number of generally longitudinally extending serpentine conductor elements each comprising a series of element portions which periodically change direction relative to one another in a plane of the substrate, or cutting one or more planar substrates to form a multiple number of generally longitudinally extending serpentine substrate elements each comprising a series of element portions which periodically change direction relative to one another in a plane of the substrate, so that said serpentine conductor elements are cut from the larger substrate back-to-back with similarly oriented element portions of the serpentine conductor elements being cut from common parts of the larger substrate across a width of the substrate and forming a layer of an HTS on a surface of the serpentine substrate elements, and
interleaving such serpentine conductor elements to form a longitudinally extending transposed conductor HTS conductor or cable.

2. A method according to claim 1 including forming a layer of an HTS on one or more planar substrates and cutting the substrate(s) to form a multiple number of generally longitudinally extending serpentine conductor elements each comprising a first series of element portions having a generally common longitudinal axis and a second series of element portions having a generally common longitudinal axis which is spaced from the longitudinal axis of said first series of element portions in a plane of the substrate, with connecting portions of the conductor elements between.

3. A method according to claim 1 including cutting one or more planar substrates to form a multiple number of generally longitudinally extending serpentine substrate elements each comprising a first series of element portions having a generally common longitudinal axis and a second series of element portions having a generally common longitudinal axis which is spaced from the longitudinal axis of said first series of element portions in a plane of the substrate, with connecting portions of the substrate elements between, and forming a layer of an HTS on a surface of the serpentine substrate-elements.

4. A method according to claim 2 wherein the element portions of said first series of conductor elements and the element portions of said second series of conductor elements are longer than said connecting portions between.

5. A method according to claim 3 wherein the element portions of said first series of substrate elements and the element portions of said second series of substrate elements are longer than said connecting portions between.

6. A method according to claim 1 including forming a layer of an HTS on one or more substrates and cutting the substrate(s) with the HTS layer thereon to form a multiple number of generally longitudinally extending serpentine conductor elements each comprising a first series of spaced generally parallel element portions which extend at an angle across a longitudinal axis of the conductor element in a first direction and a second series of spaced generally parallel element portions which extend across the longitudinal axis of the conductor element in an opposite direction.

7. A method according to claim 6 including cutting the substrate(s) with the HTS layer thereon to include connecting portions of the conductor elements between adjacent ends of each of said element portion of said first series of element portions and an element portion of said second series of element portions.

8. A method according to claim 1 including cutting one or more planar substrates to form a multiple number of generally longitudinally extending serpentine substrate elements each comprising a first series of spaced generally parallel element portions which extend at an angle across a longitudinal axis of the substrate element in a first direction and a second series of spaced generally parallel element portions which extend across the longitudinal axis of the conductor element in an opposite direction.

9. A method according to claim 8 including cutting the substrate(s) to include connecting portions of the substrate elements between adjacent ends of each said element portion of said first series of element portions and an element portion of said second series of element portions.

10-26. (canceled)

27. A high temperature superconductor (HTS) conductor or cable comprising a number of transposed conductor elements which comprise a layer of an HTS on a substrate element cut in a longitudinally extending serpentine form from a larger substrate back-to-back with similarly oriented element portions being cut from common parts of the larger substrate across the width of the larger substrate.

28. An HTS conductor or cable according to claim 27 wherein said conductor elements each comprise a series of element portions which periodically change direction relative to one another in a plane of the substrate.

29. An HTS conductor or cable according to claim 28 wherein said conductor elements each comprise a first series of element portions having a generally common longitudinal axis and a second series of element portions having a generally common longitudinal axis which is spaced from the longitudinal axis of said first series of element portions in a plane of the substrate, with connecting portions of the conductor elements between.

30. An HTS conductor or cable according to claim 29 wherein the element portions of said first series of conductor elements and the element portions of said second series of conductor elements are longer than said connecting portions between.

31. An HTS conductor or cable according to claim 28 wherein said conductor elements each comprise a first series of spaced generally parallel element portions which extend at an angle across a longitudinal axis of the conductor element in a first direction and a second series of spaced generally parallel element portions which extend across the longitudinal axis of the conductor element in an opposite direction.

32. An HTS conductor or cable according to claim 31 including connecting portions of the conductor elements between adjacent ends of each of said element portion of said first series of element portions and an element portion of said second series of element portions.

33-48. (canceled)

49. A method for forming a high temperature superconductor (HTS) conductor or cable comprising transposed conductor elements comprising:
forming a layer of an HTS on one or more substrates and cutting the substrate(s) with an HTS layer thereon into a multiple number of generally longitudinally extending serpentine conductor elements, or providing a multiple number of generally longitudinally extending serpentine substrate elements and forming a layer of an HTS on a surface of said elements to form a number of conductor elements, said longitudinally extending serpentine conductor elements each comprising a first series of spaced generally parallel element portions which extend at an angle across a longitudinal axis of the conductor element in a first direction and a second series of spaced generally parallel element portions which extend across the longitudinal axis of the conductor element in an opposite direction, or
providing one or more longitudinally extending serpentine substrate element(s) and forming a layer of an HTS thereon and cutting the serpentine substrate element(s) with an HTS layer thereon into a number of shorter generally longitudinally extending serpentine conductor elements, or cutting one or more longitudinally extending serpentine substrate element(s) into a number of shorter generally longitudinally extending serpentine conductor elements and forming a layer of an HTS on the conductor elements, said longitudinally extending serpentine conductor elements each comprising a first series of spaced generally parallel element portions which extend at an angle across a longitudinal axis of the conductor element in a first direction and a second series of spaced generally parallel element portions which extend across the longitudinal axis of the conductor element in an opposite direction, and
interleaving such serpentine conductor elements to form a longitudinally extending transposed conductor HTS conductor or cable.

50. A method according to claim 49 including cutting one or more planar substrates to form a multiple number of generally longitudinally extending serpentine substrate elements each comprising a first series of spaced generally parallel element portions which extend at an angle across a longitudinal axis of the substrate element in a first direction and a second series of spaced generally parallel element portions which extend across the longitudinal axis of the conductor element in an opposite direction.

51. A method according to claim 49 including interleaving the resulting serpentine conductor elements to form a longitudinally extending HTS conductor or cable in which individual conductor elements are transposed relative to other conductor elements both in the plane of the conductor elements and orthogonal to the plane of the conductor elements.

52. A method according to claim 51 including interleaving the conductor or elements so that each serpentine conductor element is transposed with an adjacent conductor element in plane, out of plane, or both, once per each said element portion of each conductor element.

53. A high temperature superconductor (HTS) conductor or cable comprising a number of transposed conductor elements which comprise either a layer of an HTS on a substrate element cut in a longitudinally extending serpentine form from a larger substrate or a layer of an HTS applied to a substrate element having a longitudinally extending serpentine form, said conductor elements each comprising a first series of spaced generally parallel element portions which extend at an angle across a longitudinal axis of the conductor element in a first direction and a second series of spaced generally parallel element portions which extend across the longitudinal axis of the conductor element in an opposite direction.

54. An HTS conductor or cable according to claim 53 wherein the conductor elements are interleaved so that individual conductor elements are transposed relative to other conductor elements both in the plane of the conductor elements and orthogonal to the plane of the conductor elements.

55. An HTS conductor or cable according to claim 54 wherein the conductor elements are interleaved so that individual conductor elements are transposed with an adjacent conductor element either in plane, out of plane, or both, once per each said element portion of each conductor element.

56. A high temperature superconductor (HTS) conductor or cable comprising a number of transposed conductor elements which comprise either a layer of an HTS on a substrate element cut in a longitudinally extending serpentine form from a larger substrate or a layer of an HTS applied to a substrate element having a longitudinally extending serpentine form, at least some of the conductor elements being oriented such that the HTS layers of adjacent conductor elements face and directly or indirectly electrically contact each other at points along the length of the conductor or cable.

57. An HTS conductor or cable according to claim 56 wherein about half of the conductor elements are oriented such that the HTS layers of adjacent conductor elements face and directly or indirectly electrically contact each other at points along the length of the conductor or cable.

58. An HTS conductor or cable according to claim 56 wherein said conductor elements each comprise a series of element portions which periodically change direction relative to one another in a plane of the substrate.

59. An HTS conductor or cable according to claim 58 wherein said conductor elements each comprise a first series of element portions having a generally common longitudinal axis and a second series of element portions having a generally common longitudinal axis which is spaced from the longitudinal axis of said first series of element portions in a plane of the substrate, with connecting portions of the conductor elements between.

60. An HTS conductor or cable according to claim 59 wherein the element portions of said first series of conductor elements and the element portions of said second series of conductor elements are longer than said connecting portions between.

61. An HTS conductor or cable according to claim 56 wherein said conductor elements each comprise a first series of spaced generally parallel element portions which extend at an angle across a longitudinal axis of the conductor element in a first direction and a second series of spaced generally parallel element portions which extend across the longitudinal axis of the conductor element in an opposite direction.

62. An HTS conductor or cable according to claim 61 including connecting portions of the conductor elements between adjacent ends of each of said element portion of said first series of element portions and an element portion of said second series of element portions.

63. An HTS conductor or cable according to claim 56 wherein the conductor elements are interleaved so that individual conductor elements are transposed relative to other conductor elements both in the plane of the conductor elements and orthogonal to the plane of the conductor elements.
